(19) United States
(12) Patent Application Publication
(10) Pub. No.: US 2011/0068404 A1
(43) Pub. Date: Mar. 24, 2011

(54) SEMICONDUCTOR DEVICE AND METHOD FOR MANUFACTURING THE SAME

(75) Inventors: Kuniaki SUGIURA, Fujisawa-shi (JP); Takeshi KAJIYAMA, Yokohama-shi (JP); Yoshiaki ASAO, Sagamihara-shi (JP)

(73) Assignee: KABUSHIKI KAISHA TOSHIBA, Tokyo (JP)

(21) Appl. No.: 12/726,300

(22) Filed: Mar. 17, 2010

(30) Foreign Application Priority Data
Sep. 18, 2009 (JP) 2009-218106

(51) Int. Cl. H01L 29/78; H01L 21/336

(52) U.S. Cl. 257/365; 438/283; 257/E29.264; 257/E21.421

(57) ABSTRACT

A semiconductor device includes a first semiconductor layer and a second semiconductor layer that have a form of fins and are arranged a predetermined distance apart from each other, in which a center portion of each serves as a channel region, and side portions sandwiching the center portion serve as source/drain regions, a gate electrode formed on two side surfaces of each of the channel regions of the first semiconductor layer and the second semiconductor layer, with a gate insulating film interposed therebetween, an insulating film formed to fill a gap between the source/drain regions of the first semiconductor layer and the source/drain regions of the second semiconductor layer, and silicide layers formed on side surfaces of the source/drain regions of the first semiconductor layer and the source/drain regions of the second semiconductor layer that are not covered by the insulating film.

### CROSS-REFERENCE TO RELATED APPLICATIONS

This application is based upon and claims the benefit of priority from prior Japanese Patent Application No. 2009-218106, filed Sep. 18, 2009, the entire contents of which are incorporated herein by reference.

### BACKGROUND OF THE INVENTION

1. Field of the Invention

The present invention relates to a semiconductor device and a method for manufacturing the semiconductor device.

2. Description of the Related Art

As transistor patterns become finer, researches have been conducted to seek prevention of the drive current reduction.

One method for preventing the drive current from being lowered is to form a metal oxide semiconductor field-effect transistor (MOSFET) comprising a channel region in semiconductor fins. Such a MOSFET, called “fin MOSFET”, has a greater channel width than a conventional planar MOSFET. With this structure, the device can be made smaller but receive a larger drive current (see Jpn. Pat. Appln. KOKAI Publication No. 2002-9289, for example).

Furthermore, in order to increase the drive current of a fin MOSFET, it is important to reduce a contact resistance between a semiconductor and silicide in a source/drain regions of the transistor. However, if a width of the fin becomes smaller in the narrow-side direction to reduce the cell size and suppress a leakage current, the entire fins of the source/drain regions are changed to silicide when forming silicide layers on the source/drain regions. With the fins of the source/drain regions that entirely become silicide, the semiconductor of the channel region is brought into direct contact with the silicide, resulting in a large contact resistance. In order to prevent the contact resistance from increasing, a technology has been suggested in which an epitaxial semiconductor film such as silicon is selectively forming and thickened in the source/drain regions so that the fins are prevented from becoming silicide (see Jpn. Pat. Appln. KOKAI Publication No. 2005-86024, for example). The use of epitaxial growth, however, increases the cost.

It therefore has been difficult to facilitate the fabrication of a fin transistor with a large drive current.

### BRIEF SUMMARY OF THE INVENTION

According to a first aspect of the present invention, there is provided a semiconductor device comprising: a first semiconductor layer and a second semiconductor layer that have a form of fins and are arranged a predetermined distance apart from each other, in which a center portion of each serves as a channel region, and side portions sandwiching the center portion serve as source/drain regions; a gate electrode formed on two side surfaces of each of the channel regions of the first semiconductor layer and the second semiconductor layer, with a gate insulating film interposed therebetween; an insulating film formed to fill a gap between the source/drain regions of the first semiconductor layer and the source/drain regions of the second semiconductor layer; and silicide layers formed on side surfaces of the source/drain regions of the first semiconductor layer and the source/drain regions of the second semiconductor layer that are not covered by the insulating film.

According to a second aspect of the present invention, there is provided a method for manufacturing a semiconductor device, comprising: forming a first semiconductor layer and a second semiconductor layer in form of fins a predetermined distance apart from each other; forming a gate insulating film and a gate electrode in center portions of the first semiconductor layer and the second semiconductor layer; introducing impurities into regions of the first semiconductor layer and the second semiconductor layer that are not covered by the gate electrode to form a pair of source/drain regions in each of the first semiconductor layer and the second semiconductor layer; forming an insulating film in such a manner as to cover the source/drain regions of the first semiconductor layer and the source/drain regions of the second semiconductor layer and fill a gap therebetween; etching the insulating film to leave the insulating film between the source/drain regions of the first semiconductor layer and the source/drain regions of the second semiconductor layer; and forming silicide films on side surfaces of the source/drain regions of the first semiconductor layer side surfaces and of the source/drain regions of the second semiconductor layer that are not covered by the insulating film.

### BRIEF DESCRIPTION OF THE SEVERAL VIEWS OF THE DRAWING

FIG. 1 is a bird's eye view for schematically showing a fundamental structure of a semiconductor device according to an embodiment of the present invention.

FIG. 2A is a plan view for schematically showing the fundamental structure of the semiconductor device according to the embodiment of the preset invention; FIG. 2B is a section view along line A-A of FIG. 2A; and FIG. 2C is a section view along line B-B of FIG. 2A.

FIG. 3A is a plan view for schematically showing part of a fundamental semiconductor device manufacturing method according to an embodiment of the present invention; and

FIG. 3B is a section view for schematically showing part of the fundamental semiconductor device manufacturing method according to the embodiment of the present invention.

FIG. 4A is a plan view for schematically showing part of the fundamental semiconductor device manufacturing method according to the embodiment of the present invention; and

FIG. 4B is a section view for schematically showing part of the fundamental semiconductor device manufacturing method according to the embodiment of the present invention.

FIG. 5A is a plan view for schematically showing part of the fundamental semiconductor device manufacturing method according to the embodiment of the present invention; and

FIG. 5B is a section view for schematically showing part of the fundamental semiconductor device manufacturing method according to the embodiment of the present invention.

FIG. 6A is a plan view for schematically showing part of the fundamental semiconductor device manufacturing method according to the embodiment of the present invention; FIG. 6B is a section view along line A-A of FIG. 6A; and FIG. 6C is a section view along line B-B of FIG. 6A.

FIG. 7A is a plan view for schematically showing part of the fundamental semiconductor device manufacturing method according to the embodiment of the present invention; FIG. 7B is a section view along line A-A of FIG. 7A; and FIG. 7C is a section view along line B-B of FIG. 7A.

FIG. 8A is a plan view for schematically showing part of the fundamental semiconductor device manufacturing method according to an embodiment of the present invention; and FIG. 8B is a section view along line B-B of FIG. 8A.

FIG. 9A is a plan view for schematically showing part of the fundamental semiconductor device manufacturing method according to the embodiment of the present invention; and

FIG. 9B is a section view along line B-B of FIG. 9A.

FIG. 10A is a plan view for schematically showing part of the fundamental semiconductor device manufacturing method according to the embodiment of the present invention; and

FIG. 10B is a section view along line B-B of FIG. 10A.

### DETAILED DESCRIPTION OF THE INVENTION

Exemplary embodiments of the present invention will be described in detail below with reference to the attached drawings. In the following embodiments, a fin transistor will be dealt with.

### Embodiments

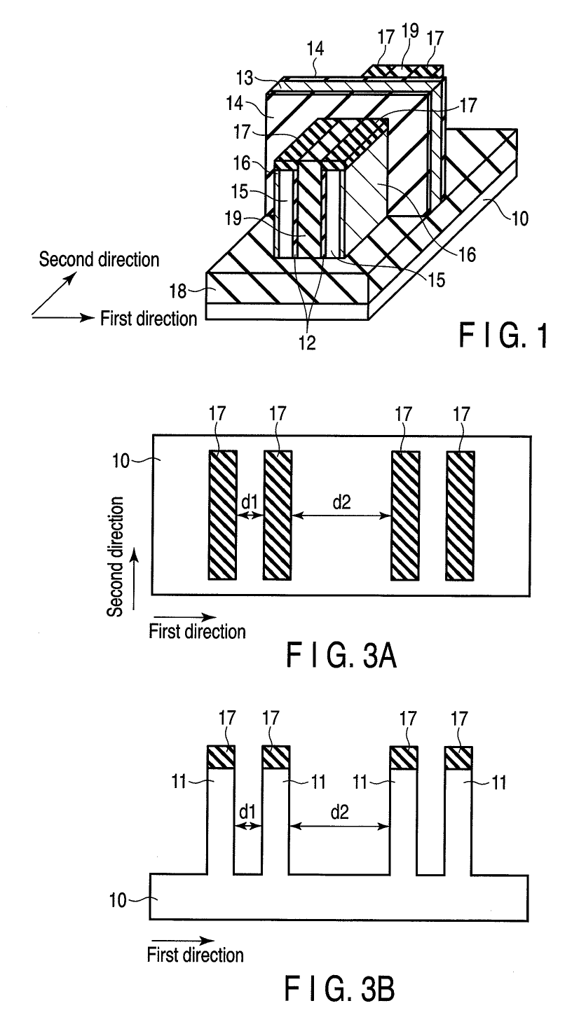

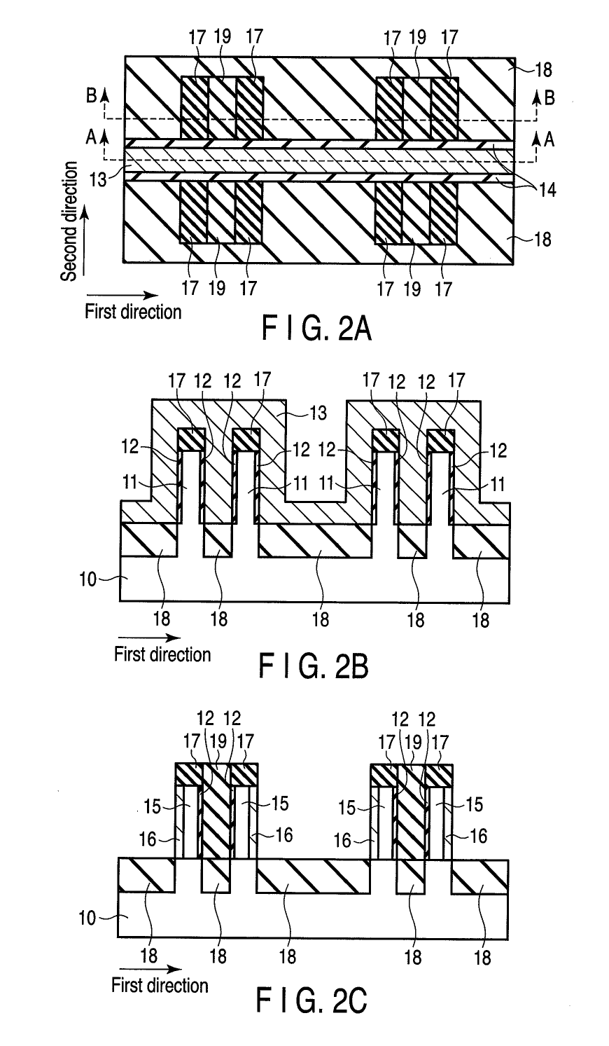

The fundamental structure of a semiconductor device according to an embodiment of the present invention will be explained with reference to FIGS. 1, 2A and 2B. FIG. 1 is a bird's eye view that schematically shows the fundamental structure of the semiconductor device according to the present embodiment. FIG. 2A is a plan view that schematically shows the fundamental structure of the semiconductor device according to the present embodiment. FIG. 2B is a section view along line A-A of FIG. 2A, while FIG. 2C is a section view along line B-B of FIG. 2A.

As illustrated in FIGS. 1, 2A and 2B, a semiconductor substrate 10 is provided with fin-like semiconductor layers 11 having a width of, for example, 40 nm along the first direction and a length of, for example, 120 nm along the second direction. Each of the semiconductor layers 11 comprises a channel region and a pair of source/drain regions 15 sandwiching the channel region in the second direction. According to the present embodiment, the two semiconductor layers 11 form one cell, and the distance between the two semiconductor layers 11 (the first semiconductor layer 11 and the second semiconductor layer 11) is greater than the distance between the present pair (the present cell) of the first semiconductor layer 11 and the second semiconductor layer 11 and its adjacent pair (another cell) of semiconductor layers 11 (the third and fourth semiconductor layers 11). The distance between the two semiconductor layers 11 (the first semiconductor layer 11 and the second semiconductor layer 11) is approximately 40 nm, while the distance between the two adjacent cells is approximately 240 nm.

An isolation insulating film 18 is formed of a silicon oxide film on the semiconductor substrate 10 and around the bottoms of the semiconductor layers 11. Then, several-nanometer-thick gate insulating films 12 are formed of silicon oxide films on the opposed surfaces (first surfaces) of the first and second semiconductor layers 11 and the not-opposed surfaces (second surfaces) of the first and second semiconductor layers 11 in the vicinity of the channel region. Furthermore, cap layers (mask layers) 17 are formed of a silicon nitride film on the top surfaces of the first and second semiconductor layers 11. Then, a gate electrode 13 is formed, for example, of polysilicon on the gate insulating films 12 and the cap layers 17 in such a manner as to extend in the first direction. Gate electrode protective films 14 are formed of a silicon nitride film on the surfaces of the gate electrode 13 that are parallel to the first direction.

Insulating films (stopper insulating films) 19 are formed of a silicon oxide layer between the opposing first surfaces of the source/drain regions of the first semiconductor layer and the second semiconductor layer to serve as silicide stoppers. Silicide films 16 are formed on the not-opposed second surfaces of the source/drain regions of the first semiconductor layer and the second semiconductor layer.

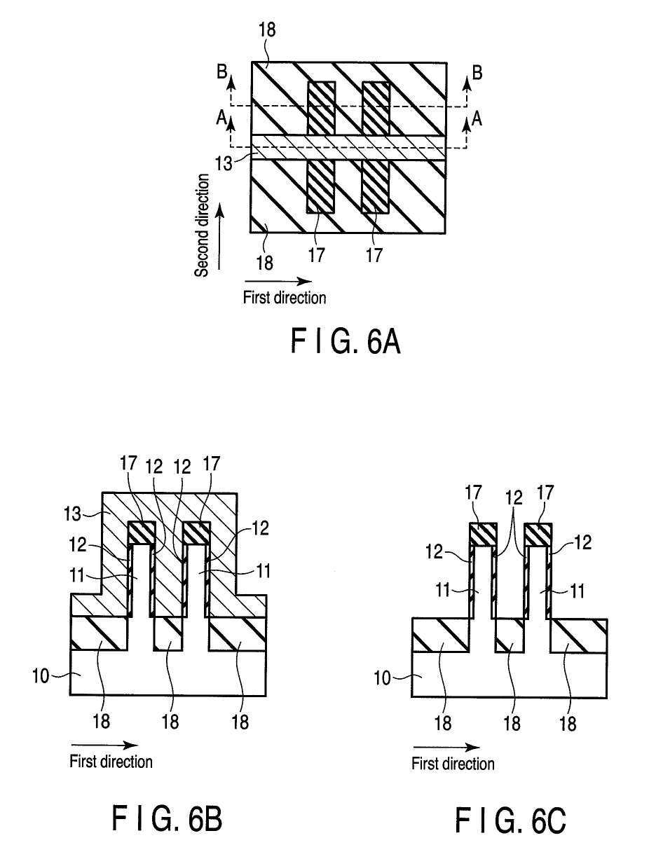

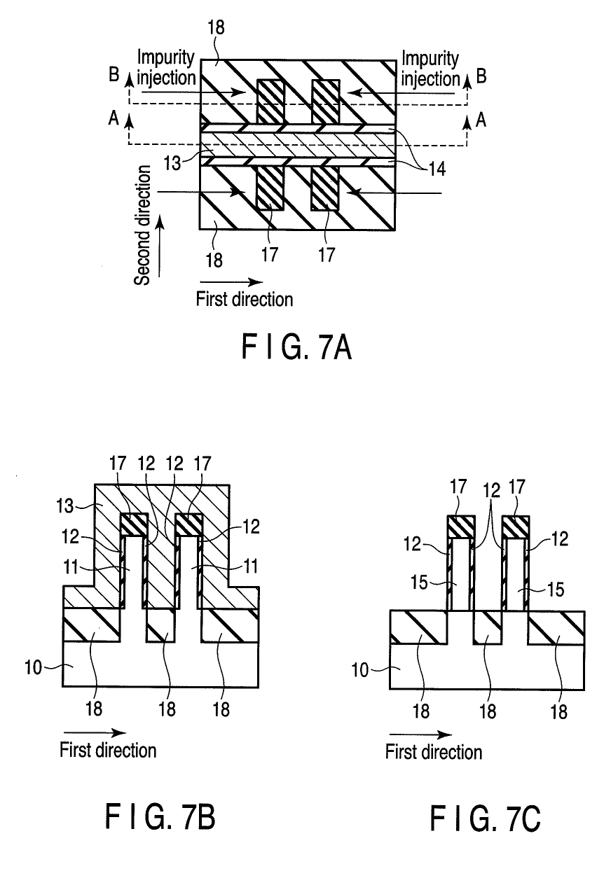

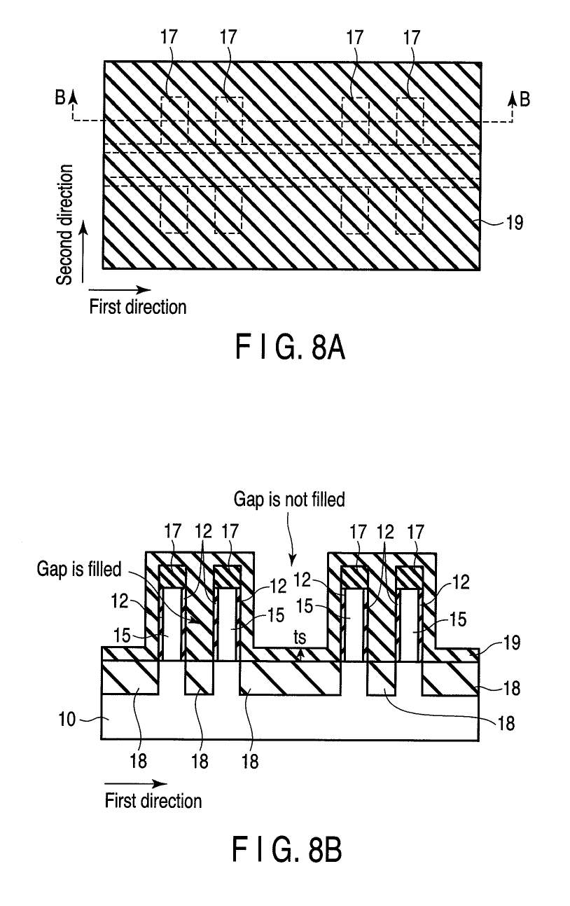

Next, the fundamental method for manufacturing the semiconductor device according to the present embodiment will be explained with reference to FIGS. 3A, 3B, 4A, 4B, 5A, 5B, 6A, 6B, 6C, 7A, 7B, 7C, 8A, 8B, 9A, 9B, 10A and 10B. FIGS. 3A, 4A and 5A are plan views that schematically show part of the fundamental method for manufacturing the semiconductor device according to the present embodiment, and FIGS. 3B, 4B and 5B are section views that schematically show part of the fundamental method for manufacturing the semiconductor device according to the present embodiment. FIGS. 6A and 7A are plan views that schematically show part of the fundamental method for manufacturing the semiconductor device according to the present embodiment, FIGS. 6B and 7B are section views along line A-A of FIGS. 6A and 7A, and FIGS. 6C and 7C are section views along line B-B of FIGS. 6A and 7A. FIGS. 8A, 9A and 10A are plan views that schematically show part of the fundamental method of manufacturing the semiconductor device according to the present embodiment, and FIGS. 8B, 9B and 10B are section views along line B-B of FIGS. 8A, 9A and 10A.

First, as illustrated in FIGS. 3A and 3B, fins (the first and second semiconductor layers) 11 are deposited on the semiconductor substrate 10 a predetermined distance apart from each other. To form the fins 11, mask layers (cap layers) 17 are deposited on the semiconductor substrate 10 by photolithography, and the semiconductor substrate 10 is etched by performing anisotropic dry etching such as reactive ion etching (RIE) by use of the mask layers 17 as masks. The fins 11 extend in the second direction orthogonal to the first direction. The fins 11 have a width of 40 nm in the first direction, for example, and a length of 120 nm in the second direction, for example. Every two fins 11 form one cell, with a distance d1 therebetween, and an adjacent cell is arranged a distance d2 away from the cell. Distance d1 is less than distance d2. Distance d1 is approximately 40 nm, while distance d2 is approximately 80 nm. For the semiconductor substrate 10, a silicon on insulator (SOI) substrate comprising a p-type semiconductor region, an embedded insulating film deposited on the p-type semiconductor region, and an n-type semiconductor region deposited on the embedded insulating film may be adopted. In addition, silicon nitride films may be adopted for the mask layers 17.

When fins 11 are to be formed in fine patterns, the sidewall transfer process as suggested in a reference document, A. Kaneko et al., IEDM Tech. Dig., p. 863 (2005) may be employed.

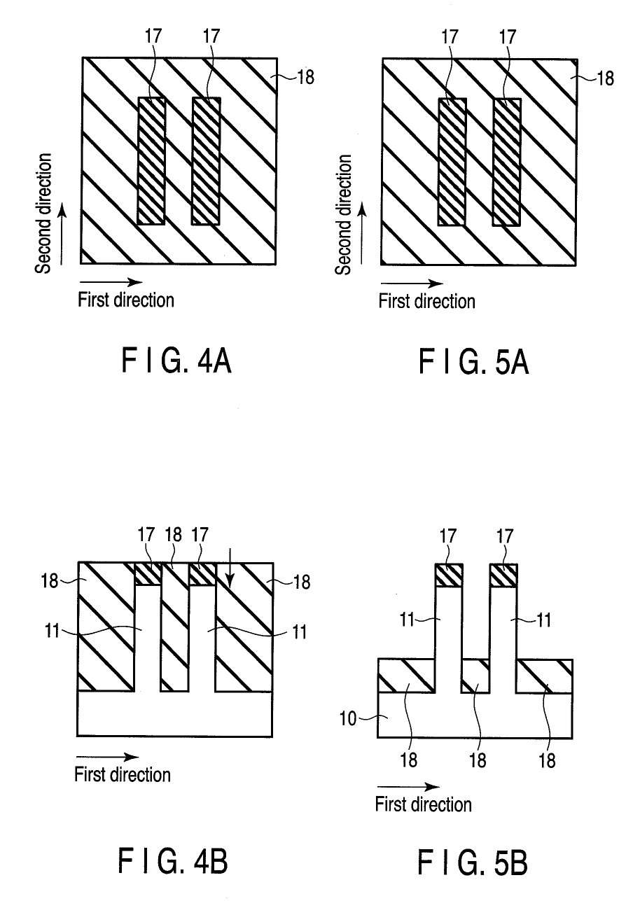

Next, as illustrated in FIGS. 4A and 4B, a silicon oxide film is prepared by chemical vapor deposition (CVD) or the like to form the isolation insulating film 18, and the silicon oxide film is planarized by chemical mechanical polishing (CMP) or the like until the top ends of the mask layers 17 are exposed.

Thereafter, as illustrated in FIGS. 5A and 5B, the isolation insulating film 18 is removed to reach a predetermined depth by anisotropic dry etching or the like. Here, the isolation insulating film 18 is selectively etched.

Next, as illustrated in FIGS. 6A, 6B and 6C, a silicon oxide film is prepared one to several nanometers thick is prepared on the surface regions of the fins 11 on their sides by thermal oxidation or the like to form the gate insulating films 12. Then, polysilicon is deposited to form the gate electrode film 13. For the gate insulating films 12, hafnium oxide films may be adopted. Furthermore, for the gate electrode film 13, a conductive film of highly doped polysilicon or tungsten is adopted. Mask layers that are not shown in the drawings are deposited on the gate electrode film 13 by photolithography, and the gate electrode 13 is thereby arranged on part of the fins 11 and the gate insulating film 12 by anisotropic dry etching by use of the mask layers as masks. The gate electrode 13 extends in the first direction. Moreover, the gate electrode 13 has a width of approximately 20 nm in the second direction.

Then, as illustrated in FIGS. 7A, 7B and 7C, silicon nitride films are formed by CVD or the like, to form the gate sidewall protective films 14, and, after anisotropic dry etching is conducted, approximately 10-nm-wide gate sidewall protective films 14 remain on the sides of the gate electrode 13 only. Thereafter, the source/drain regions 15 are formed by injecting impurities into the fins 11 by ion injection or the like, from the sides of the fins 11 that are not covered by the gate electrode 13 and the gate sidewall protective film 14. After impurities are injected, a heat treatment may be conducted, if necessary, to obtain the source/drain regions 15.

Next, as illustrated in FIGS. 8A and 8B, a silicon oxide film is deposited by CVD or the like to form the insulating film 19. Here, the thickness of the silicon oxide film 19 is adjusted in such a manner that a gap between the two source/drain regions 15 (fins 11) of the cell is filled but a gap between any two adjacent cells is not filled. In particular, when the thickness of the silicon oxide film 19 is ts, the width between the two source/drain regions 15 of the same cell is d1, and the width between two adjacent cells is d2 (FIGS. 3A and 3B), the thickness ts is greater than or equal to d1/2, and less than d2/2.

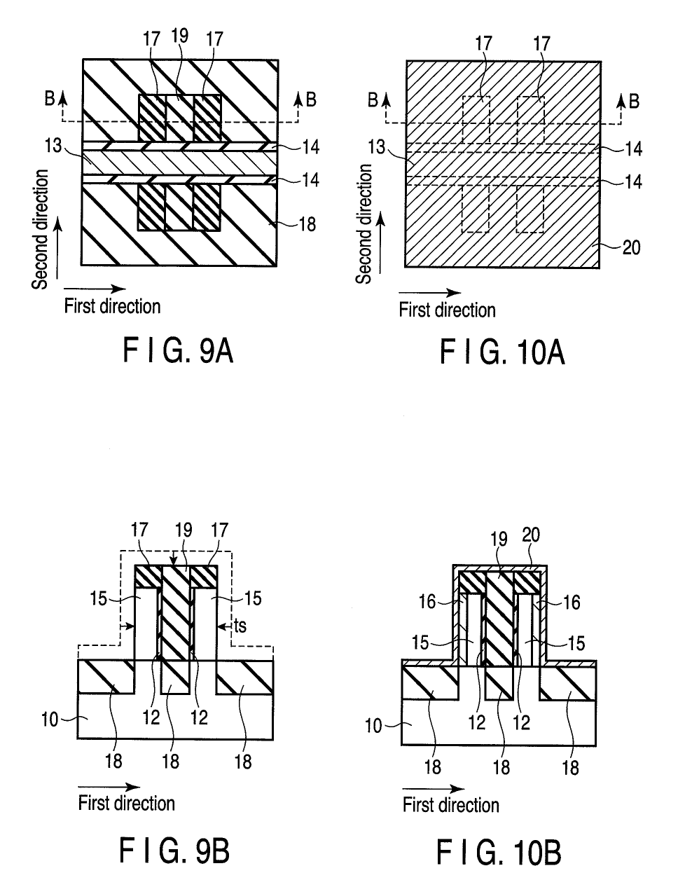

Next, as illustrated in FIGS. 9A and 9B, the silicon oxide film 19 is etched so that the not-opposed side surfaces (second sides) of the two source/drain regions 15 of the same cell become exposed, with the insulating film 19 remaining between the opposed side surfaces (first sides). For this etching, isotropic etching such as wet etching and high-radical-density plasma etching is adopted, and the silicon oxide film 19 is etched off for a depth corresponding to the thickness ts. The insulating film 19 and the gate sidewall protective films 14 should be formed of different materials so that the gate sidewall protective films 14 would not be removed during the etching process. For example, if silicon nitride films are used for the gate sidewall protective films 14, a silicon oxide film should be used for the insulating film 19. Furthermore, because the gate insulating films 12 are thin, exposed portions of the gate insulating films 12 are etched off in the etching process.

Thereafter, as illustrated in FIGS. 10A and 10B, a silicide material metal film 20 is entirely formed of Co, Ni or the like, and subjected to a thermal treatment so that the silicide films 16 are formed on the not-opposed side surfaces of the two source/drain regions 15 of the cell. Because the insulating film 19 is formed between the opposed first surfaces of the two source/drain regions 15 of the cell, silicide would not be formed on the first surfaces of the source/drain regions 15. Furthermore, a thermal treatment is conducted thereon so that the entire source/drain regions 15 would not be changed to the silicide films 16.

Next, as illustrated in FIGS. 1, 2A and 2B, the metal film that is not reacted in the silicide reaction is selectively etched away.

Then, after the known interconnect formation process (not shown in the drawings) and the like is performed, the semiconductor device is completed.

According to the above embodiment, cells, each of which comprises two fins 11, are formed a predetermined distance apart from one another. Distance d1 between the two fins of a cell is less than distance d2 between two adjacent cells. For this reason, by determining the thickness is of an insulating film 19 to be greater than or equal to d1/2, the insulating film 19 can be embedded between the opposed side surfaces of the two fins 11 (the source/drain regions 15) of the cell. As a result, when forming silicide on the side surfaces of the fins 11 (source/drain regions 15), the silicide material metal film 20 is not formed between the opposed side surfaces (first sides) of the two fins 11 (source/drain regions 15) of the cell, and a silicide reaction occurs only in the other sides (second sides) of the fins 11. Hence, even if the fins 11 (source/drain region 15) have a small thickness in the first direction, the fins 11 (source/drain region 15) are prevented from entirely changing to silicide.

If the entire source/drain regions 15 become silicide films 16, the contact resistance of the contact region between the semiconductor layers 11, which are channel regions, and the silicide films 16 would be increased. However, because the source/drain regions 15 are not entirely changed to silicide films 16, and contact regions of the silicide films 16 and the source/drain regions 15 are provided, the contact resistance is significantly reduced in the contact regions of the silicide films 16 and the source/drain regions 15. Thus, by preventing the source/drain regions 15 from entirely becoming the silicide films 16, a parasitic resistance can be reduced, and a fin transistor having a high drive current can be achieved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a first semiconductor layer and a second semiconductor layer comprising fins arranged apart from each other by a predetermined distance, each fin comprising a channel region disposed between two source/drain regions;
a gate electrode on two side surfaces of each of the channel regions of the first semiconductor layer and the second semiconductor layer, with a gate insulating film interposed therebetween;
an insulating film to fill a gap between the source/drain regions of the first semiconductor layer and the source/drain regions of the second semiconductor layer; and
silicide layers on side surfaces of the source/drain regions of the first semiconductor layer and the source/drain regions of the second semiconductor layer that are not covered by the insulating film.

2. The device according to claim 1, further comprising gate electrode protective films on the side surfaces of the gate electrode between the gate electrode and the insulating film.

3. The device according to claim 2, wherein the insulating film and the gate electrode protective films comprise of different material from each other.

4. The device according to claim 2, wherein the insulating film comprises a silicon oxide film, and the gate electrode protective films comprise of silicon nitride films.

5. The device according to claim 1, wherein a distance between the first semiconductor layer and a second semiconductor layer is less than the distance between the first semiconductor layer and a fin-shaped semiconductor layer of a cell adjacent to the first semiconductor layer.

6. The device according to claim 1, further comprising cap layers on top surfaces of the first and second semiconductor layers.

7. The device according to claim 6, wherein the cap layers are silicon nitride films.

8. A method for manufacturing a semiconductor device, comprising:
forming a first semiconductor layer and a second semiconductor layer comprising fins apart from each other by a predetermined distance;
forming a gate insulating film and a gate electrode in center portions of the first semiconductor layer and the second semiconductor layer;
adding impurities into regions of the first semiconductor layer and the second semiconductor layer that are not covered by the gate electrode to form a pair of source/drain regions in each of the first semiconductor layer and the second semiconductor layer;
forming an insulating film to cover the source/drain regions of the first semiconductor layer and the source/drain regions of the second semiconductor layer and to fill a gap therebetween;
etching the insulating film to leave the insulating film between the source/drain regions of the first semiconductor layer and the source/drain regions of the second semiconductor layer; and
forming silicide films on side surfaces of the source/drain regions of the first semiconductor layer side surfaces and of the source/drain regions of the second semiconductor layer that are not covered by the insulating film.

9. The method according to claim 8, wherein forming the first and second semiconductor layers comprises forming cap layers on a semiconductor substrate and conducting anisotropic etching with the cap layers as masks.

10. The method according to claim 8, further comprising forming gate electrode protective films on the side surfaces of the gate electrode between the gate electrode and the insulating film.

11. The method according to claim 10, wherein the insulating film and the gate electrode protective films comprise of different materials from each other.

12. The method according to claim 10, wherein the insulating film is a silicon oxide film, and the gate electrode protective films are silicon nitride films.
